(19) United States
(12) Patent Application Publication
(10) Pub. No.: US 2005/0145969 A1
(43) Pub. Date: Jul. 7, 2005

(54) Back-illuminated msm module

(76) Inventors: Peter Gulden, Munchen (DE); Martin Vossiek, Hildesheim (DE)

Correspondence Address: PAUL AND PAUL, 2900 TWO THOUSAND MARKET STREET, PHILADELPHIA, PA, 19103, US

(21) Appl. No.: 10/481,501

(22) PCT Filed: Jun. 12, 2002
(86) PCT No.: PCT/DE02/02151

(30) Foreign Application Priority Data
Jul. 5, 2001 (DE) 101 32 583.5

(51) Int. Cl. H01L 31/00

(52) U.S. Cl. 257/449

(57) ABSTRACT

The invention relates to a BIMSM element (M,M′), in which at least the substrate (1,1′), the electrode pair (2) and the photosensitive layer (3) are combined in a monolithic structure. According to the invention, at least one electrode of the electrode pair (2) can be used to induce a modulation voltage, at least one electrode of the electrode pair (2) can be used to decouple a mixed product and the MSM element (M,M′) can be used as an electro-optical mixer.

The invention relates to a back-illuminated MSM element as an electrooptical mixer, a corresponding MSM array and a process for producing the MSM element.

For determination of the phase difference between an incident electromagnetic wave and a corresponding modulation voltage, electrooptical mixers are known, based on metal-semiconductor-metal (“MSM”) structures, see MacDonald and Swekla 1990; Liu and MacDonald 1993; Ruff, Bruno et al., 2000; Shen, Stead et al. 2000).

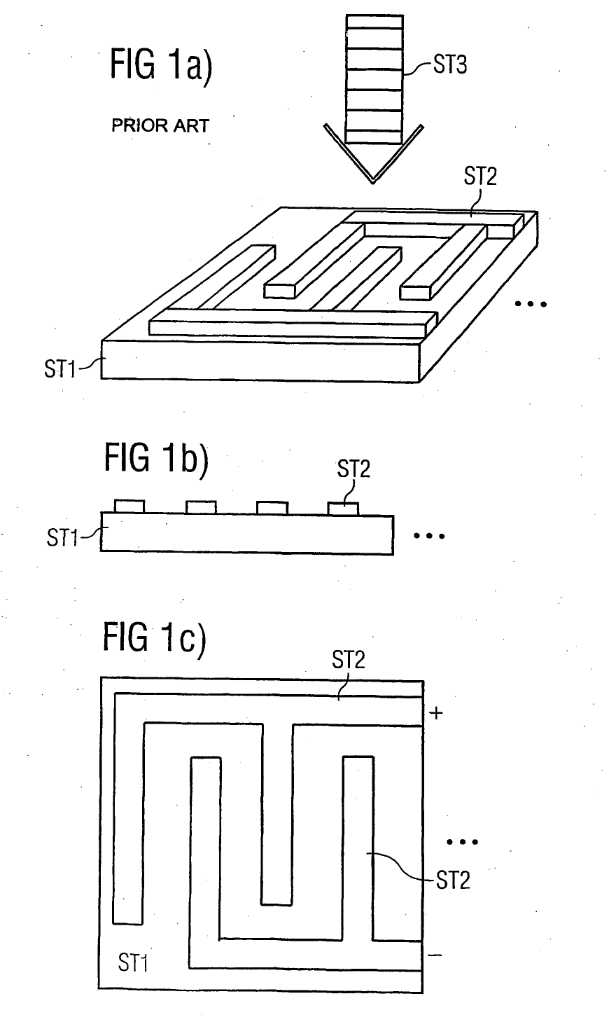

To date, front-illuminated MSM (FIMSM) elements have been used as electrooptical mixers, see FIG. 1, which have some disadvantages:
the electrodes used cover parts of the light-sensitive semiconductor, the sensitivity of the MSM element being reduced as a result;
as the electrodes lie on the illuminated surface, the MSM element must be contacted either from there by means of so-called “wire bonds”, making connection lines necessary, or expensive vias must be run as far as the underside of the semiconductor;
the field of the electrodes extends into the semiconductor only to a limited depth. Therefore, photoelectrons generated at a relatively great depth are subject to only very weak field strengths, or special, expensive semiconductor materials with high absorption such as e.g. GaAs must be used;
the integration of further functions in the semiconductor is restricted or very complex.

As a pure photodetector, a so-called “back-illuminated MSM” (BIMSM) element is also used. In the case of the BIMSM element, it is not the side with the metallization or with the electrodes that is illuminated, but the back (Kim, Griem et al. 1992). This avoids the covering of the photosensitive semiconductor on the illuminated side, and the BIMSM element can be contacted directly on the metallized side, e.g. by means of flip-chip technology.

However, BIMSM elements still have a few problems:
the semiconductor must be very thin, which means that it has to be thinned out, which is expensive and causes problems during handling;
further integration of readout electronics and application circuits is possible only with great difficulty.

It is the object of the present invention to provide a BIMSM structure which works reliably, makes possible a simple integration of the readout functions, and is comparatively simple to handle and can be produced cheaply and flexibly.

This object is achieved by means of an MSM element according to patent claim 1, an MSM array according to claim 9 and a production process according to claim 12.

The MSM can be back-illuminated (BIMSM) and has at least one substrate, at least one electrode pair attached above, e.g. directly thereto, and at least one light-sensitive layer, in turn directly attached thereto, e.g. a semiconductor layer. The monolithic construction can e.g. be achieved in particular by coating. However, further additional parts can also be monolithically connected to it, such as e.g. a passivation layer, an intermediate insulating layer or contacting means. Due to the monolithic structure of the BIMSM element there is no need for the connection technology required hitherto, e.g. the attaching of wire bonds, which means an increase in reliability and makes possible smaller structures with a higher degree of integration.

The difficult and costly handling and finishing of the semiconductor layer, e.g. for thinning out, is also dispensed with. The MSM element can in many cases be produced by standard processes in one production step. This also applies to MSM arrays with several MSM elements or units or also to larger MSM modules in which other elements are also applied to the substrate, e.g. evaluation electronics. The MSM element can be used as an electrooptical mixer, with at least one electrode of the electrode pair being able to be used to couple in a modulation voltage and at least one electrode of the electrode pair being able to be used to decouple a mixing product; the choice of electrode is not restricted; e.g. it can be the same electrode, or both electrodes can be used for coupling in and/or out, e.g. using a suitable filter or mixer.

It is advantageous if the light-sensitive layer is coated with a passivation layer on its illuminated surface. It is also favourable to have an insulating layer between substrate and electrodes, in particular using vias through the insulating layer for the electrical connection of substrate and electrode structure. It is also favourable if a reflective layer, e.g. a metal film, is applied to that side of the light-sensitive layer that faces away from the illuminated surface.

It is also favourable if an electronic component, in particular an ASIC produced using VLSI technology, is integrated into the substrate of the BIMSM element. It is favourable if the light-sensitive layer is integrated into the electronic component in crystalline form, in particular if the basic material of substrate and light-sensitive layer is the same, favourably Si.

It is advantageous if the photo-sensitive layer is applied as an amorphous thin film.

It can also be advantageous if the substrate consists of an electrically insulating material, in particular glass or ceramic, in particular if additional components, e.g. a separate evaluation unit or pixel electronics are situated on the substrate (modular design) which have been applied e.g. by means of flip-chip technology.

It is also advantageous if the layer thicknesses of the BIMSM elements are chosen such that the permeability of the boundary surface to the light-sensitive layer is wavelength-selective, in particular if the layer thicknesses correspond to a quarter of the preferred wavelength or a multiple thereof.

Also inventive is an MSM array which has at least two MSM elements (pixels) in particular if these MSM elements are connected to common modulation electronics, and/or which has at least one integrated evaluation circuit. An MSM array is preferred in which, in each pixel individually, a readout circuit is integrated for individual operation as a photoelectric mixer.

For simplified construction, it is advantageous if the frequency-dependent amplification is chosen such that there is no need for an upstream filter.

The MSM element can be produced, preferably using VLSI (Very Large Scale Integrated) technology such that the electrode pair, optionally with an intermediate layer or embedded in one layer, are applied on the substrate coated and at least the electrode pair is coated in such a manner that the light-sensitive layer forms thereon.

In the following embodiments the invention is represented schematically in greater detail:

FIG. 1 shows an FIMSM element according to the state of the art in oblique view (FIG. 1a), side view (FIG. 1b), and top view (FIG. 1c);

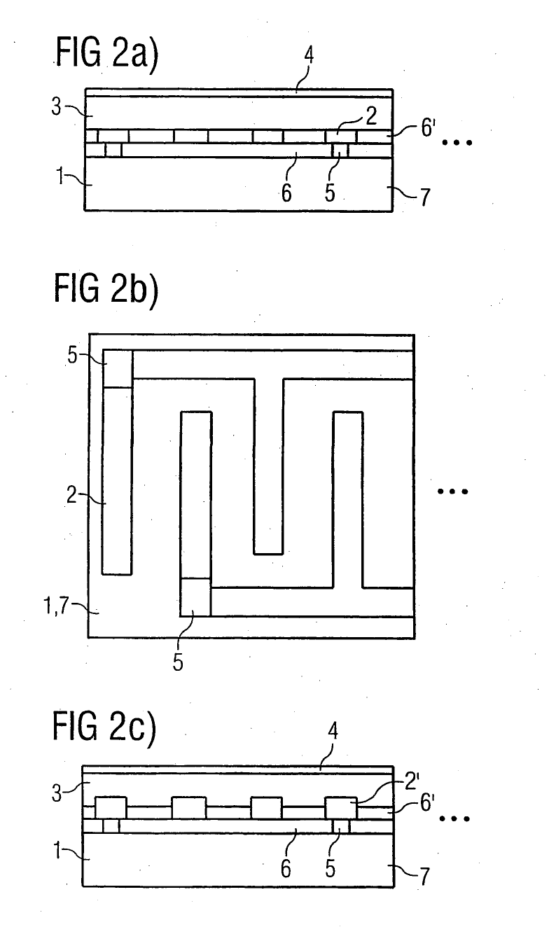

FIG. 2 shows a sandwich BIMSM module in side view (FIG. 2a) and top view (FIG. 2b) as well as in side view with extended electrodes (FIG. 2b);

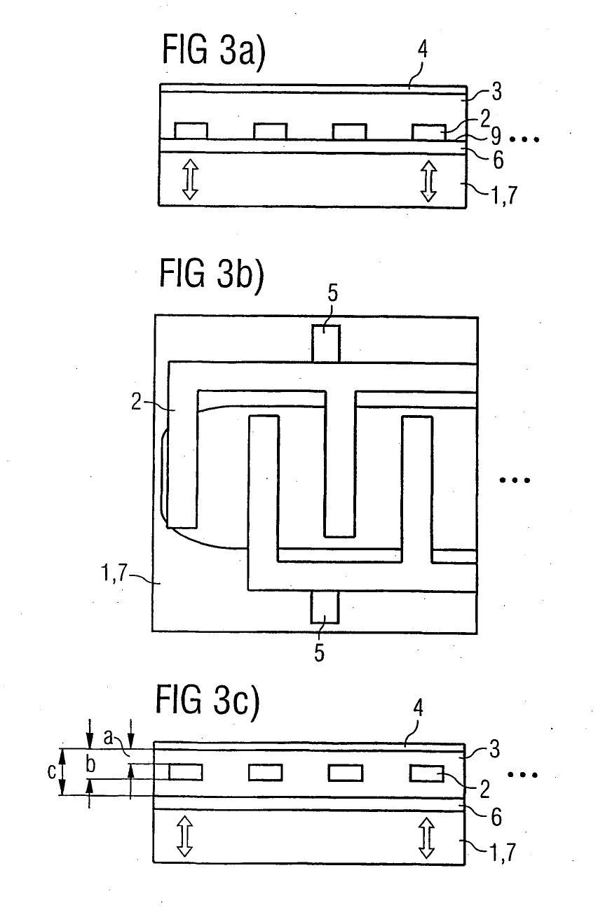

FIG. 3 shows a further sandwich BIMSM module;

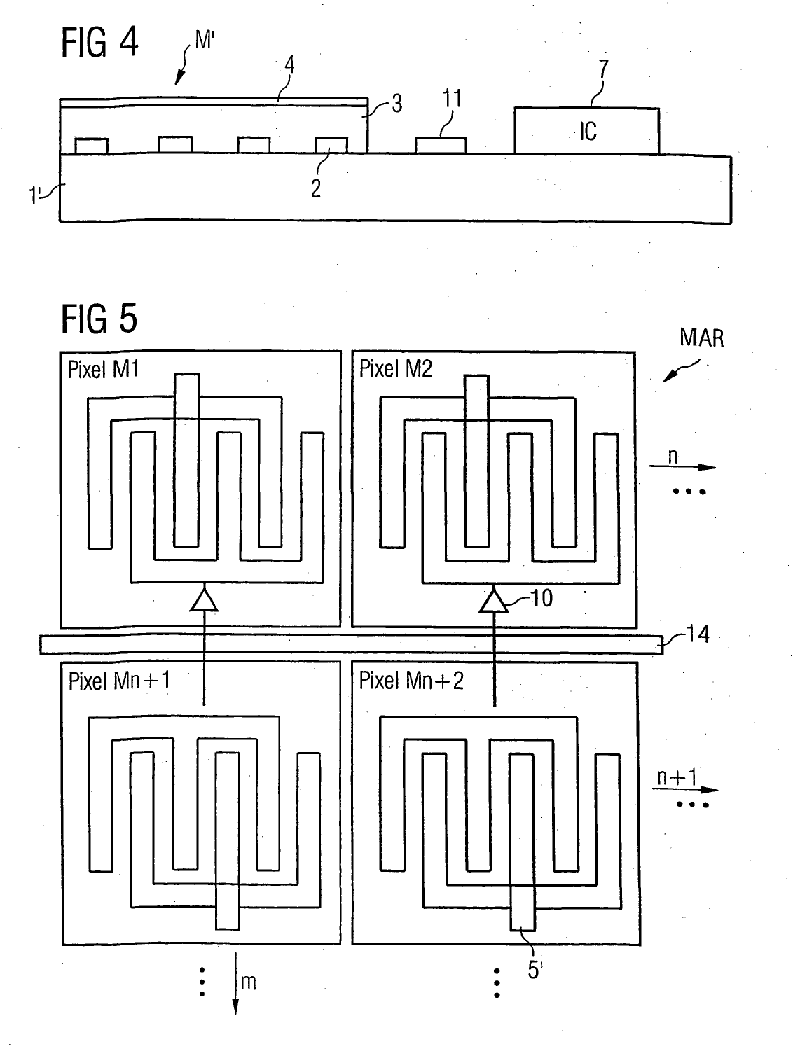

FIG. 4 shows a further sandwich BIMSM module;

FIG. 5 shows an MSM array;

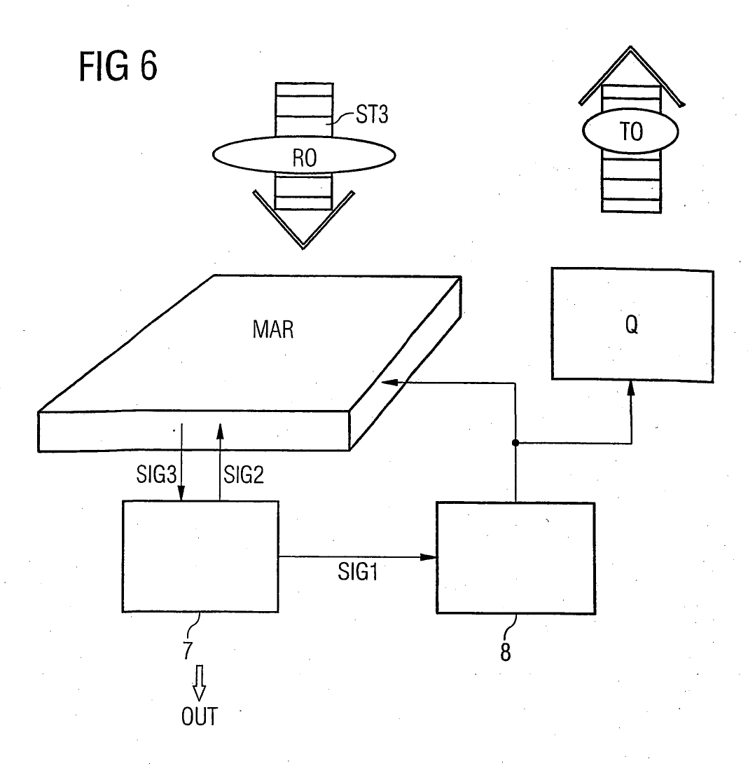

FIG. 6 shows an MSM system;

FIG. 1 shows an outline of a front-illuminated MSM element (FIMSM), which, as symbolized by the dots, is continued on the right side.

The front-illuminated MSM element is produced by applying a metal layer to a non- or weakly-doped semiconductor substrate ST1 and structuring it in finger form. The fingers/finger electrodes ST2 are connected with each other oppositely directed and are operated with a differential voltage as bias. If this differential voltage is modulated and at the same time the MSM element is illuminated with intensity-modulated light ST3 of the same modulation frequency, a phase difference can then be determined from the mixing product.

This FIMSM element is connected via its electrodes ST2 to other components, e.g. evaluation electronics, using methods of connection technology, e.g. by means of wire bonds.

Previously, during use as a BIMSM element, after the production of the photosensitive semiconductor substrate ST1, the latter has had to be thinned out in a downstream process step, which makes handling expensive. Contacts with other components can in this case e.g. also be achieved by means of a flip-chip process.

FIG. 2 shows a BIMSM element produced monolithically as a layered composite (“sandwich BIMSM element”). Onto a substrate in the form of an electronic component 1, here: of an ASIC, are applied a first insulating layer 6 and then a metal (finger) electrode pair 2 using thin-film technology, preferably by means of standard VLSI processes according to Baker, J. R.; Li, H. W. et al. 1998. The electronic component 1 contains for example a readout and further processing unit 7 or, e.g. in the case of configuration in an MSM array MAR, pixel electronics 8. The electrode pair 2 is embedded in a second insulating layer 6′. FIG. 2b shows a top view of the geometry of the electrode pair 2 with the position of the vias 5. A light-sensitive layer 3 is in turn applied to the electrode pair 2 in the form of a semiconductor thin layer of doped amorphous Si. The semiconductor thin layer is coated with a passivation layer 4. For coupling the electrode pair 2 and the electronic component 1, through-contacting means (vias) 5 are run pointwise through the first insulation layer 6, their position being adjustable to the use in question, see FIG. 2b. The electrode pair 2 can however also be connected via side feed lines 5′, see e.g. FIG. 3b. The first insulating layer 6 can also be dispensed with, if the electrodes 2 can be accommodated without it on the electronic component 1; it is however favourable for the reduction of interference and for improved field propagation. The material of the second insulating layer 6′, which is also optional, is preferably the same as that of the first insulating layer 6, i.e. embedded therein. For process engineering details, see e.g. Böhm, Blecher et al. 1998.

The advantage of this construction lies in the numerous possible combinations of different materials, in particular of the semiconductor materials, and in the enabling of extremely high filling coefficients.

FIG. 2a shows a sandwich BIMSM element in which the electrodes 2 lie inside the second insulating layer 6′, as a result of which the light-sensitive layer 3 can be applied very easily and does not need to be finished, e.g. thinned out. In order to improve the field distribution and thus increase the degree of modulation, the electrodes 2′ can also project into the light-sensitive layer 3, as shown in FIG. 2c.

Materials are preferably chosen which can be satisfactorily used in standard CMOS technology, e.g. Pd, Au and other noble metals for the electrode structure 2 and the vias 5, as well as SiO₂ for the insulating layers 6, 6′. The material of the light-sensitive layer 3 is not restricted to semiconductors but can also comprise e.g. polymers, which show the photoelectrical effect. As light-sensitive semiconductor layer, amorphous silicon inter alia is suitable, optionally doped. The optional passivation layer 4 is preferably transparent. The electronic component 1 is preferably constructed using silicon technology, but not restricted to this. By using several thin layers lying on top of each other, further effects e.g. the avalanche or tunnel effect, can be used.

In FIG. 3 the light-sensitive layer 3 consists of the same semiconductor basic material as the electronic component 1, favourably Si. In the light-sensitive layer 3, the Si can be suitably doped, see Sze 1969; Pierret 1996, Sze 1998. In this embodiment the application of the first insulating layer 6 has been dispensed with, the photosensitive layer 3 thus lies directly on the electronic component 1. Because the electronic component 1 generally consists of several layers, e.g. semiconductor/metal/insulator, in this version, it is no longer possible to distinguish between the electronic component 1 and the other MSM structures, the MSM structure can be seen as part of the electronic component 1. Thus the MSM element M can also be designed such that an electronic component 1, in particular an ASIC produced using VLSI technology, is integrated in the substrate.

This procedure is cheaper than using different semiconductors for the electronic component 1 and the light-sensitive layer 3, as one process step is dispensed with. However a comparatively smaller filling coefficient can also possibly result, as well as only a limited possible use of different semiconductor materials.

The electrodes 2 lie either under the light-sensitive layer 3, see FIG. 3a, or embedded inside the light-sensitive layer 3, see FIG. 3c.

Preferably the materials and processes known from CMOS cameras are used. The electrodes 2 are produced by suitable structuring of the metal layers inside the ASIC. The decoupling of the mixing signal and the coupling-in of the modulation can either be carried out analogously to the previous embodiment by connection with deeper-lying metallization layers, or laterally through feed lines, which create a connection to outside of the parts lying in the same layer.

In both the embodiments presented, the decoupling of the mixing signal can take place either inside the electronic component 1, or by means of externally attached filter circuits. The electronic module 1, here: the ASIC, can itself either be contacted by means of standard wire bonds from the side, or with a suitable arrangement of the pads under the ASIC, by means of flip-chip technology, e.g. fine-pitch flip-chip technology.

FIG. 4 shows a sandwich BIMSM structure M′ in which a semiconductor substrate is not used, but the electrodes 2 are applied directly onto an insulating substrate 1′, in particular a ceramic or glass substrate, see e.g. L.-H. Laih 1999, and then coated with one or more light-sensitive semiconductor layers 3. The electrodes 2 can either be flat, or, in order to improve the field distribution, project into the light-sensitive layer 3. In this version the separation between mixing signal and modulation signal is carried out by means of a discrete filter 11 realized on the substrate. The values can then be recorded directly from the external periphery, e.g. in an integrated circuit IC applied to the substrate 1′, here a readout and/or further processing unit 7, stored and/or further processed.

This process makes possible a cost-favourable realization of structures with large surface areas. In the case of substrates 1′ which can be correspondingly structured, e.g. LTCC ceramics and/or high-frequency ceramics, the readout circuit 7 and further electronics, optionally in conjunction with discrete components 11, IC, can be produced directly in modular form on the substrate 1′, e.g. using flip-chip technology.

Generally, i.e. also in all three versions, the combination of electrodes 2 and light-sensitive layer 3 can be chosen such that either a Schottky or an ohmic transition forms. Moreover, correspondingly doped n-i-n transitions can also be used. With regard to the above-mentioned transitions, see inter alia Sze 1969, Pierret 1996; Sze 1998.

For layers 2, 3, the thin-film combinations mentioned in Fischer 1996 are used, as these are compatible with standard processes. Also of particular interest is the formation of the electrodes 2 and vias 5 and feed lines 5′ from different metals, in order to produce at one point a Schottky transition e.g. in the case of the electrodes 2-photo-sensitive layer 3 contact, and at another point, on the other hand, an ohmic contact, e.g. in the case of the electrodes 2-evaluation circuit 7 contact.

Generally, i.e. also in all three versions, a preferred embodiment involves choosing the layer thicknesses e.g. the thicknesses a, b, c in FIG. 3, such that they correspond to a fraction or a multiple of the fraction of the incident wavelength and the fraction is chosen such that the air -light-sensitive layer 3, passivation layer 4-light-sensitive layer 3, or air-light-sensitive layer 3 transition is wavelength-selective. Preferred fractions are one quarter and odd multiples thereof. Either e.g. the whole layer c, or the part a above the electrodes, the electrode thickness b-a and the part c-b under the electrodes can be accordingly chosen.

Moreover, the sensitivity can generally be increased if there is, after the light-sensitive layer 3, a reflective transition onto the next layer, whereby non-absorbed light is cast back into the light-sensitive layer 3, where it then still absorbs. This is also favourable for realizing a thinner layer. The reflection at the end of the light-sensitive layer can, inter alia, be produced by a different refractive index of the nearest semiconductor layer or by incorporating a thin metal layer 9.

Moreover, a transparent passivation layer 4 can be applied to the light-sensitive layer 3, e.g. in order to prevent a surface oxidation or wear. This passivation layer 4 can in addition be designed as an anti-reflection layer or in conjunction with the transition between the photosensitive layer 3 and the layer lying beneath it, form a Fabry-Perot or Bragg resonator, see on this point Kowalsk and Prank 1993; Litvin, Burm et al. 1993 and Bassous, Halbout et al. 1994.

Suitable operating circuits for the use of FIMSM elements as electrooptical mixers can be found in Ruff, Bruno et al. 2000; Shen, Stead et al. 2000. It is possible in principle to distinguish between unilateral and bilateral modulation. In a usual circuit, the voltage is modulated at one of the two finger structures with a specific frequency. The other finger is set to a constant bias voltage, and the mixing signal is decoupled by means of a filter. Such a readout circuit is favourably also integrated in each pixel M1, . . . , Mmn of the sandwich-BIMSM structure. Preferably the frequency-dependent amplification of the integrated amplifiers is chosen such that there is no need for an upstream filter. A particular advantage of this arrangement is that a decoupling of the modulated electrodes 2 of all pixels M1, . . . , Mmn is dispensed with, i.e. these are simply connected and runs directly to the contact.

FIG. 5 shows a BIMSM array MAR with a number of (m×n) MSM elements M1, M3, Mn+1, Mn+2, . . . (pixels) which can be continued in two directions n/m, as indicated by the dots and arrows. Should the capacity of all the connected modulation electrodes become too great, drivers 10 can be integrated, e.g. in the substrate 1, for the modulation voltage, e.g. in each pixel M1, M2, . . . , Mn+1, Mn+2, . . . , Mnm (indicated by the triangles), or in the case of arrangement in the array MAR at the beginning of each array line 1 . . . n /1. . . m.

In many cases a greater technical outlay may be required to suppress interference signals. Both electrodes of the respective electrode pair 2 are then modulated complementarily, and the mixing product is decoupled at each of the two electrodes 2. In this version the modulation signal is fed in via a common conductor 14; via lateral contacting means 5′, the pixels M1, M2, . . . , Mn+1, Mn+2, . . . , Mnm are connected to pixel electronics 8 (not represented) which supply the bias, filter and amplify an output signal and optionally store the signal and include an address logic.

Common interference can then be suppressed by means of subtraction, similar to the state of the art for PMD sensors (Schwarte 1997; Schwarte 1997). Such a circuit is preferably integrated into each pixel M1, M2, . . . , Mn+1, Mn+2, . . . , Mnm. The problem of the decoupling of the individual pixels can occur for example either by capacitive coupling in of the modulation signals of each pixel M1, M2, . . . , Mn+1, Mn+2, . . . , Mnm or by integration of an amplifier 12 into each pixel M1, M2, . . . , Mn+1, Mn+2, . . . , Mnm. Reading out takes place behind the amplifier 12; as previously, either a filter 11 or a suitable readout amplifier or readout unit 7 is integrated.

The reading out of the corresponding signals can take place e.g. according to Böhm, Blecher et al. 1998 either as current or voltage readout. The readout circuits 7, storage possibilities and addressing methods of the pixel electronics 8 are preferably implemented in each pixel M1, M2, . . . , Mn+1, Mn+2, . . . , Mnm. Of particular interest are processes with high dynamics, e.g. according to Lulé, Keller et al. 1999. In the case of bilateral modulation, it is favourable for processes and arrangements, in particular for subtraction according to Schwarte 1997;Schwarte 1997 to be integrated into each pixel M1, M2, Mn+1, Mn+2, Mnm.

Also favourable are MSM elements into which sigma-delta converters are integrated; see, analogously to this, Gulden, Vossiek et al. 2000 for PMDs.

The “sandwich-MSM” mixers can then be described with the modulation processes described for PMD structures, e.g. IQ, Pseudo Noise, (Schwarte 1997; Schwarte 1997), 2-frequency, FSCW, FMCW (Gulden, Vossiek et al. 2000). Moreover an electrooptical regulation loop, inter alia for distance measurement, can be realized, see e.g. Gulden, Vossiek et al. 2000.

Due to the clearly increased system improvements, in particular in relation to bandwidth, dynamics and accuracy, new uses and measurement ranges can be opened up by “sandwich-MSM” structures.

FIG. 6 shows a system for distance measurement using a monolithic MSM array MAR. The system has a light source Q for the radiation of modulated light, e.g. a laser diode or an LED, with downstream transmission optics TO. The system also contains receiver optics RO for focussing the incident modulated light ST3, which then falls onto the MSM array MAR. The incident light can be focussed by using optics and lenses already used for CMOS sensors or PMD systems, see Tai, Schwarte et al. 2000.

The MSM array MAR can be controlled by means of a readout and/or further processing unit 7, for example a computer, a digital signal processor, a microprocessor or an FPGA. The readout and/or further processing unit 7 receives data SIG3 from the MSM array MAR and delivers a gating signal SIG2 to the latter. In this embodiment it also transmits measurement data OUT, e.g. data relating to distance measurement, delivers a gating signal SIG1 for the pixel electronics 8 (here: modulation electronics), which in turn controls the MSM array MAR and the light source Q.

Such a system can be used e.g. to monitor a seating position in a car (Mengel and Doemens 1997; Doemens and Mengel 1998). A similar system can also be used for monitoring the outside space of the car (Schwarte, Buxbaum et al. 2000). Preferred realizations of these systems use infrared light, so as not to disturb the driver. Of particular interest is compliance with eye-safety regulations, which is facilitated by the use of light with a wavelength greater than 1400 mn, and suitable reception materials. Suitable materials according to the state of the art are listed inter alia in Sze 1969; Pierret 1996; Sze 1998. Preferred fitting positions are directly behind the windscreen, or in the existing headlights.

Comparable systems with direct current readout can be used according to the invention as phase detectors in electrooptical regulation loops, e.g. in a PLL, as phase detectors for clock synchronization or as demodulators e.g. in CDMA or QPSK communications systems (Buxbaum, Schwarte et al. 2000).
Baker, J. R., Li, H. W. et al. (1998). CMOS. Circuit Design; Layout and Simulation; IEEE 1998
Bassous, E., J.-M. Halbout et al. (1994). High Speed Silicon-Based Lateral Junction Photodetectors Having Recessed Electrodes and Thick Oxide to Reduce Fringing Fields. 5,525,828. United States, International Business Machines Corporation: 28.
Böhm, M., F. Blecher, et al. (1998). High Dynamic Range Image Sensors in Thin Film on ASIC Technology for Automotive Applications. Advanced Microsystems for Automotive Applications 98, Springer.
Buxbaum, B., R. Schwarte, et al. (2000). Optisches CDMA auf Basis der PMD-Technologie. Symposium “Optik in der Rechentechnik 2000”, Hagen.
Doemens, G and P. Mengel (1998). Verfahren und Vorrichtung zur Aufnahme eines dreidimensionalen Entfernungsbildes. DE 198 33 207 A 1. Germany, Siemens AG: 14.
Fischer, H. (1996). Ein analoger Bildsensor in TFA (Thin Film on ASIC) Technology. Elektrotechnik. Siegen, Universitat GH Siegen: 133.
Gulden, P. G., M. Vossiek, et al. (2000). PMD Element. Munich, Siemens ZT MS 1: 18.
Gulden, P. G., M. Vossiek, et al. (2000). PMD System. Germany, Siemens AG: 34.
Gulden, P. G., M. Vossiek, et al. (2000). Verfahren und Vorrichtungen zum Betrieb eines PMD-System. Germany: 42.
Kim, J. H., H. T. Griem, et al. (1992). “High-performance back-illuminated InGaAs/InA1As MSM photodetector with a record responsivity of 0.96 A/W.” IEEE PHOTONICS TECHNOLOGY LETTERS 4(11): 1241-1244.
Kowalsky, W. and U. Prank (1993). Planar MSM-modulators and photodetectors with integrated Fabry-Perot resonator for arrayed configurations in high bandwidth optical interconnects. SPIE Optoelectronic Interconnects, SPIE.
L.-H. Laih, T.-C., Y.-A. Chen, W.-C. Tsay, T.-S. Jen, J.-W. Hong (1999). “Amorphous metal-semiconductor-metal photodector (MSM-PD) with bottom ridged Cr electrodes.” Electronics Letters 35 (12): 1021-1022.
Litvin, K., J. Burm, et al. (1993). High Speed Optical Detectors for Monolithic Milimeter Wave Integrated Circuits. IEEE MTT-S International Microwave Symposium Digest, Atlanta, IEEE.
Liu, Q. Z. and R. I. MacDonald (1993). “Controlled nonlinearity monolithic integrated optoelectronic mixing receiver.” IEEE PHOTONICS TECHNOLOGY LETTERS 5(12): 1403-1406.
Lulé, T., H. Keller, et al. (1999). 100.000 Pixel 120 dB Imager for Automotive Vision. Advanced Microsystems for Automotive Applications 99, Berlin, Springer.
MacDonald, R. I. and B. E. Swekla (1990). “Frequency domain optical reflectometer using a GaAs optoelectronic mixer.” Applied Optics 29 (31): 4578-4582.
Mengel, P. and G. Doemens (1997). Verfahren und Vorrichtung zur Aufnahme eines mehrdimensionalen Entfernungsbildes. DE 197 57 595 A 1. Germany, Siemens AG: 9.
Pierret, R. F. (1996). Semiconductor Device Fundamentals. Reading, Massachusetts, Addison-Wessley Publishing Company.
Ruff, W., J. Bruno, et al. (2000). Self-mixing detector candidates for an FM/cw ladar architecture. SPIE Laser Radar Technology and Applications V, SPIE.
Schwarte, R. (1997). Verfahren und Vorrichtung zur Erfassung von Phasen-und Amplitudenelektromagnetischen Wellen. DE 197 04 496 A 1. Germany, R. Schwarte: 26.
Schwarte, R., Buxbaum, et al. (2000). New powerful sensory tool in Automotive Safety Systems Based on PMD-Technology. Advances in Automotive Imaging, Springer Verlag?
Shen, P. H., M. Stead, et al. (2000). Interdigitated finger semiconductor photodetector. SPIE Aerosense, 24-28 April 2000, SPIE.
Sze, S. M. (1969). Physics of Semiconductor Devices. New York, John Wiley & Sons.
Sze, S. M. (1998). Modern Semiconductor Devices. New York, Wiley.
Tai, W., Schwarte, R. et al. (2000). Optimisation of the light transmission and irradiance distribution of an aspherical lens for 3-D time-of-flight sensors
VDE (1994). Sicherheit von Laser-Einrichtungen, Part 1 DIN EN 60825-1, VDE 0837, Part 1, VDE/DIN: 77.

1. Back-illuminated MSM element (M, M′), having at least
one substrate (1,1′),
a electrode pair (2) attached above the substrate (1,1′),
at least one light-sensitive layer 3, at least attached to the electrode pair (2), which can be illuminated on the side facing away from the electrode pair (2),
characterized in that
at least the substrate (1,1′), the electrode pair (2) and the light-sensitive layer (3) are jointly monolithically structured,
at least one electrode of the electrode pair (2) can be used for coupling in a modulation voltage,
at least one electrode of the electrode pair (2) can be used for decoupling a mixing product,
the MSM element (M, M′) can be used as an electrooptical mixer.

2. MSM element (M, M′) according to claim 1, in which the light-sensitive layer (3) is coated with a passivation layer (4).

3. MSM element (M, M′) according to one of claims 1 or 2, in which there is a first insulating layer (6) between the substrate (1,1′) and electrode pair (2).

4. MSM element (M) according to one of claims 1 to 2, in which an electronic component, in particular an ASIC produced in VLSI technology, is integrated in the substrate (1).

5. MSM element (M) according to claim 4, in which the light-sensitive layer (3) is integrated in crystalline form in the electronic component (1).

6. MSM element (M′) according to one of claims 1 to 2, in which the substrate is an insulating layer (1′), in particular of ceramic or glass.

7. MSM element (M) according to one of the previous claims 1-2, in which the light-sensitive layer (3) is applied as an amorphous thin film, in particular with silicon as basic material.

8. MSM element (M, M′) according to one of the previous claims 1-2, the layer thicknesses (a, b, c) of which are chosen such that the permeability of the boundary surface to the light-sensitive layer (3) is wavelength-sensitive, in particular if the layer thicknesses (a, b, c) correspond to a quarter or a multiple of the preferred wavelength.

9. MSM array (MAR), having at least two MSM elements (M,M′) each with integrated evaluation circuits (7), in particular connected to common pixel electronics (8).

10. MSM array (MAR) according to claim 9, in which a readout circuit (7) is individually integrated in each MSM element (M,M′).

11. MSM array (MAR) according to claim 9 or 10, in which the frequency-dependent amplification is chosen such that there is no need for an upstream filter.

12. Process for producing an MSM element (M, M′) in which
the substrate (1, 1′) is coated at least with the conductor structure (2),
at least the conductor structure (2) is coated so that the semiconductor structure (2) forms thereon.
